(19) United States
(12) Patent Application Publication
(10) Pub. No.: US 2026/0130295 A1
(43) Pub. Date: May 7, 2026

(54) SEMICONDUCTOR PACKAGE AND A METHOD FOR FORMING THE SAME

(71) Applicant: STATS ChipPAC Management Pte. Ltd., Singapore (SG)

(72) Inventors: JiSeon LEE, Incheon (KR); BumRyul MAENG, Incheon (KR); YeJi AHN, Gyeonggi (KR)

(21) Appl. No.: 19/377,017

(22) Filed: Nov. 2, 2025

(30) Foreign Application Priority Data
Nov. 1, 2024 (CN) 202411553379.9

(51) Int. Cl. H01L 23/498; H01L 21/56; H01L 23/31; H01L 25/065

(52) U.S. Cl. CPC H10W 90/701; H10W 74/019; H10W 74/117; H10W 90/00

(57) ABSTRACT

A method for forming a semiconductor package comprises: providing a molded interposer module, wherein the molded interposer module comprises an interposer having at least one central opening and a chip mounting region surrounding the at least one central opening, a plurality of semiconductor chips mounted on the chip mounting region, and a mold cap formed on the chip mounting region of the interposer to encapsulate the plurality of semiconductor chips; disposing the molded interposer module on a substrate via solder paste, wherein a flux material is formed around the solder paste, and the molded interposer module and the substrate define together a space to accommodate the solder paste, and the space has side slits that communicate with an external environment; reflowing the solder paste to form solder bumps; and spraying a deflux chemical mist towards the solder bumps through the at least one central opening and the side slits.

### TECHNICAL FIELD

The present application generally relates to semiconductor technologies, and more particularly, to a semiconductor package and a method for forming a semiconductor package.

### BACKGROUND OF THE INVENTION

The semiconductor industry is constantly faced with complex integration challenges as consumers want their electronics to be smaller, faster and higher performance with more and more functionalities packed into a single device. In some semiconductor packages, a Package-in-Package (PiP) or Package-on-Package (PoP) process is utilized to combine two or more integrated circuit (IC) packages together as an integrated device. The PiP or PoP devices can more efficiently use space, and reduce lengths of signal paths between the packages. In a typical PiP or PoP device, one or more pre-molded semiconductor packages or semiconductor chips may be mounted onto another semiconductor package or substrate through an interposer or other similar structures.

However, it is noted that the number of semiconductor chips required to be mounted on a substrate increases significantly and the deployment of these semiconductor chips on the substrate is largely determined by a size of an interposer. However, in the case of Chip on Wafer (CoW) packages which are also called molded interposers, there are several process issues due to the large size of interposers, one of which is that after a large CoW package (e.g., 30mm*30mm or bigger) is attached on the substrate via solder bumps, deflux chemicals cannot penetrate through the CoW package, leaving flux residues between the CoW package and the substrate. The flux residues may deteriorate the performance and reliability of the devices.

Therefore, a need exists for further improvement to semiconductor packages or devices with large CoW or similar large-scale components.

### SUMMARY OF THE INVENTION

An objective of the present application is to provide a semiconductor package with improved reliability.

According to an aspect of the present application, a method for forming a semiconductor package is provided. The method comprises: providing a molded interposer module, wherein the molded interposer module comprises an interposer having at least one central opening passing therethrough and a chip mounting region surrounding the at least one central opening, a plurality of semiconductor chips mounted on the chip mounting region of the interposer, and a mold cap formed on the chip mounting region of the interposer to encapsulate the plurality of semiconductor chips; disposing the molded interposer module on a substrate via solder paste, wherein a flux material is formed around the solder paste, and the molded interposer module and the substrate define together a space to accommodate the solder paste, and the space has side slits that fluidly communicate the space with an external environment; reflowing the solder paste to form a plurality of solder bumps; and spraying a deflux chemical mist towards the plurality of solder bumps through the at least one central opening of interposer and the side slits.

According to another aspect of the present application, a semiconductor package is disclosed. The semiconductor package comprises: a substrate; an interposer mounted on the substrate, and having at least one central opening passing therethrough and a chip mounting region surrounding the at least one central opening; a plurality of semiconductor chips mounted on the chip mounting region of the interposer; and a mold cap formed on the chip mounting region of the interposer to encapsulate the plurality of semiconductor chips.

According to a further aspect of the present application, a method for forming a semiconductor package is disclosed. The method comprises: providing an unmolded interposer module, wherein the unmolded interposer module comprises an interposer having at least one central opening passing therethrough and a chip mounting region surrounding the at least one central opening, and a plurality of semiconductor chips mounted on the chip mounting region of the interposer; disposing the unmolded interposer module on a substrate via solder paste, wherein a flux material is formed around the solder paste, and the unmolded interposer module and the substrate define together a space to accommodate the solder paste, and the space has side slits that fluidly communicate the space with an external environment; reflowing the solder paste to form a plurality of solder bumps; and spraying a deflux chemical mist towards the plurality of solder bumps through the at least one central opening of the interposer and the side slits.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1F illustrate a method for forming a semiconductor package according to an embodiment of the present application.

FIG. 1G illustrates an exemplary layout of semiconductor chips on an interposer of the semiconductor package shown in FIG. 1A.

FIG. 1H illustrates an exemplary layout of semiconductor chips on an interposer of the semiconductor package shown in FIG. 1D.

FIG. 2 illustrates a semiconductor package according to an embodiment of the present application.

FIG. 3 illustrates a semiconductor package according to an embodiment of the present application.

FIG. 4 illustrates a semiconductor package according to an embodiment of the present application.

FIG. 5 illustrates a semiconductor package according to an embodiment of the present application.

FIG. 6A illustrates a semiconductor package according to an embodiment of the present application.

FIG. 6B illustrates an exemplary layout of semiconductor chips on an interposer of the semiconductor package shown in FIG. 6A.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, conventional large scale semiconductor packages may have reliability issues due to internal flux residues which cannot be removed completely during the manufacturing of the semiconductor packages. To address this issue, the inventors of the present application have conceived an invention of forming through holes at or close to a center of a molded interposer before it is mounted onto a substrate of the large scale semiconductor package, which allows deflux chemicals to pass therethrough into a gap between the substrate and the molded interposer, thus removing completely flux in the interior space of the semiconductor package. Without the residual flux, the performance especially reliability of the semiconductor package so formed can be improved significantly.

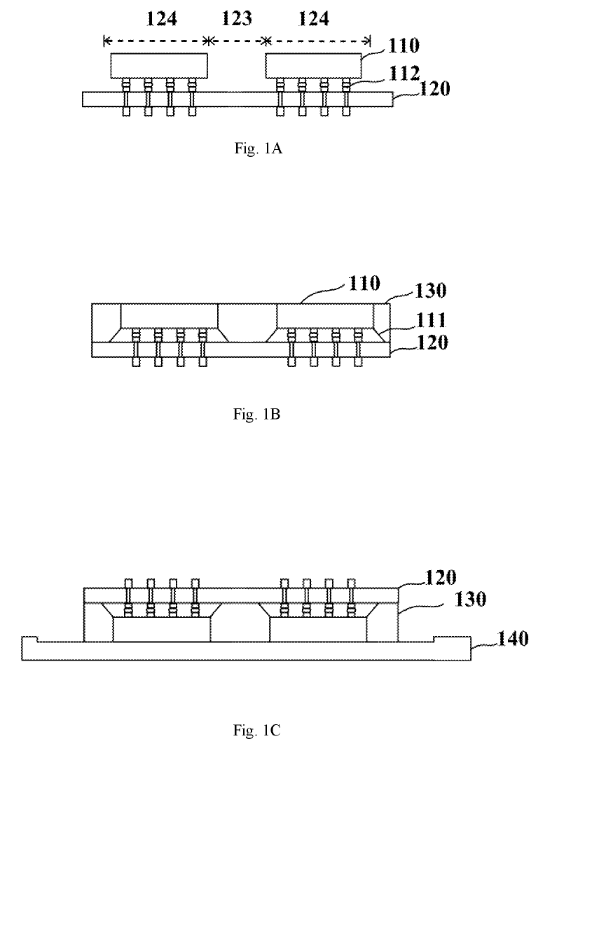

FIGS. 1A to 1F illustrate a method for forming a semiconductor package according to an embodiment of the present application. In some examples, the method can be used to make large scale semiconductor packages such as those with a size greater than 30mm*30mm. These semiconductor packages may have multiple semiconductor chips integrated therein.

As shown in FIG. 1A, an interposer 120 is provided, which includes at its back surface a set of conductive patterns such as contact pads and at its front surface another set of conductive patterns. The two sets of conductive patterns may be electrically connected with each other through conductive vias that pass through the interposer 120. A plurality of semiconductor chips 110 are mounted onto the interposer 120 via a set of interconnect structures 112 such as solder bumps or conductive posts or pillars, which are, for example, mounted on a chip mounting region of the interposer 120. The chip mounting region 124 is designed and reserved for mounting semiconductor chips, and accordingly the conductive vias passing through the interposer 120 are preferably formed in the chip mounting region. In some embodiments, the interposer 120 may have other functionalities such as redistribution, and accordingly other conductive wires may be formed in the chip mounting region. The semiconductor chips 110 may be spaced apart from each other, leaving some regions 123 of the interposer 120 unoccupied, which can be observed clearly in the layout shown in FIG. 1G. Preferably, no conductive vias or wires may be formed in at least a portion of the region(s) that are not occupied by the semiconductor chips. In some embodiments, the set of interconnect structures 112 may be solder bumps, while in some alternative embodiments, the set of interconnect structures 112 may be other interconnect components such as metal posts or e-bar modules. Besides electrically connecting the two sets of conductive patterns with each other, the interconnect structures 112 may provide mechanical support for the interposer 112 as well as components mounted thereon.

Next, as shown in FIG. 1B, an underfill encapsulant 111 may be formed between the semiconductor chips 110 and the front surface of the interposer 120. The underfill encapsulant 111 may be filled in the respective gaps between the semiconductor chips 110 and the interposer 120, so as to provide mechanical support for the connection between the semiconductor chips 110 and the interposer 120. In some examples, the underfill encapsulant 111 may include a polymer composite material, such as epoxy resin, epoxy acrylate, or polymer with or without a filler. Furthermore, a mold cap 130 may be formed on the interposer 120 to encapsulate the semiconductor chips 110. For example, the mold cap 130 may be formed using an injection molding process or a compression molding process. In some examples, the semiconductor chips 110 may have their respective top surfaces exposed from the mold cap 130, or may be completely covered by the mold cap 130. In particular, the mold cap 130 may be filled between the plurality of semiconductor chips 110 and around the semiconductor chips 110, i.e., on the unoccupied regions of the interposer 120, to enhance the attachment of the plurality of semiconductor chips 110 to the interposer 120. In some other embodiments, the mold cap 130 may be formed using paste printing, transfer molding, liquid encapsulant molding, vacuum lamination, spin coating, or any other suitable process, and may include a polymer composite material, such as epoxy resin, epoxy acrylate, or polymer with or without a filler.

It can be appreciated that although in the embodiment the interposer is illustrated as a single unit but in some other embodiments the interposer may be one unit of an interposer strip which includes multiple identical interposer units. The interposer units of the interposer strip may be processed at the same time using the same processes, and then be singulated into multiple pieces i.e., singulated into multiple molded interposer modules.

Next, as shown in FIG. 1C, the molded interposer module may be flipped over, with the back surface of the interposer 120 facing upward, and then the mold cap 130 can be attached onto a carrier 140, for example, attached onto a carrier tape. Further operations can be performed on the molded interposer module, as will be illustrated below in details.

As shown in FIG. 1D, at least one central opening 122 may be formed in the molded interposer module, which passes through the interposer 120 and the mold cap 130 thereon. In particular, the central opening 122 may be formed in the unoccupied region of the interposer 120 and between at least two of the semiconductor chips 110, as illustrated in FIG. 1H. As this region is not occupied by any semiconductor chips 110 and preferably no conductive vias or wires are formed in this region, forming the central opening 122 may not cause any damages to the semiconductor chips 110. In some embodiments, the semiconductor chips 110 may be deployed to intentionally reserve some areas of the interposer 120 for the central opening(s) 122. It can be appreciated that the central opening may be formed using etching such as laser drilling or mechanical drilling, or any other suitable processes, to the mold cap 130. The central opening 122 may be close to the center of the interposer 120, depending on where the semiconductor chips are mounted on the interposer 120. However, the central opening 122 should not be too far away from the center of the interposer 120, e.g., at a periphery of the interposer 120. A central opening far away from the center of the molded interposer module cannot allow a mist to fully penetrate and flow into the interior gap between the molded interposer module and a substrate, which will be elaborated below in more details. In some embodiments, a distance between the central opening and the center of the molded interposer module may not be greater than 1/4 of a length or a width of the molded interposer module. In some embodiments, the central opening(s) may have a depth-to-width ratio greater than 5:1, or preferably greater than 10:1.

Referring to FIG. 1H which illustrates an exemplary layout of the semiconductor chips 110 on the interposer 120, the central opening 122 is formed between the plurality of semiconductor chips 110. As the semiconductor chips may have a square or rectangular layout, the interposer 120 may preferably have a similar layout. It can be appreciated that the central opening 122 may take other shapes such as a branched shape, a circular shape, or a polygonal shape.

Next, as shown in FIG. 1E, after the central opening 122 is formed, the molded interposer module may be detached from the carrier, flipped over, and then attached onto a substrate 160. In particular, the molded interposer module may be disposed on the substrate 160 via solder paste 114. A flux material 162 may be further printed, jetted or otherwise formed around the solder paste 114. The flux material 162 can help reflowing of the solder paste in a subsequent process. Since the molded interposer module is supported on the substrate 160 at least by the solder paste 114 and is thus not in direct contact with the substrate 160, a space or gap between the interposer 120 and the substrate 160 is formed. A height of the space is generally equal to a total height of the solder paste and conductive patterns or structures below the back surface of the interposer 120. The space has side slits 164 that fluidly communicate the space with an external environment of the molded interposer module and the substrate 160. In some embodiments, additional electronic devices such as resistors, capacitors, inductors, switches, or any other suitable electronic devices may be mounted directly on the substrate 160 around the molded interposer module.

As aforementioned, the solder paste 114 needs to be reflowed, by heating or laser radiation, for example, to be transformed into solder bumps which have sufficient physical strength and can electrically and mechanically connect the molded interposer module with the substrate 160. It can be seen that the central opening separates the molded interposer module into multiple parts (at least in some sections), which can release a thermal stress of the molded interposer module that is generated during the reflowing process, and thus the molded interposer module may not warp significantly even if the molded interposer module has a large size. The molded interposer module with less warpage issues can achieve better wetting for the solder bumps, especially for those solder bumps at or close to the periphery of the molded interposer module.

After the reflowing process during which a portion of the flux material may be consumed, e.g., vaporized, a residual portion of the flux material needs to be removed from a solder bumps 168. Accordingly, as shown in FIG. 1F, a deflux chemical mist 180 can be sprayed towards the plurality of solder bumps 168 in various directions through the central opening 122 and the side slits 164. For example, the deflux chemical mist 180 may be sprayed from a top nozzle which is disposed right above the molded interposer module and aligned with the central opening 122 and multiple lateral nozzles which are disposed around the molded interposer module at an angle of 10 to 50 degrees relative to the substrate 160. As can be seen from FIG. 1F, the side slits 164 at the periphery of the molded interposer module provide passages allowing the deflux chemical mist 180 to flow into the internal space between the molded interposer module and the substrate 160, and at the same time, the central opening 122 of the molded interposer module provides another passage which also allows the deflux chemical mist 180 to flow into the internal space. Since the space may have a small height, the additional passage formed by the central opening 122 can avoid that the deflux chemical mist 180 cannot flow deep enough into the internal space and cannot be in direct contact with the residual flux material there. In this way, the residual flux material can be fully removed by the deflux chemical mist.

After the various steps shown in FIGS. 1A to 1F, the semiconductor package can be obtained. Due to the fully removal of the flux material, the semiconductor package can have a better reliability and an improved performance. In some embodiments, an encapsulant layer can be further formed on the substrate to encapsulate the molded interposer module and the additional electronic components mounted on the substrate, which is not shown in FIG. 1F.

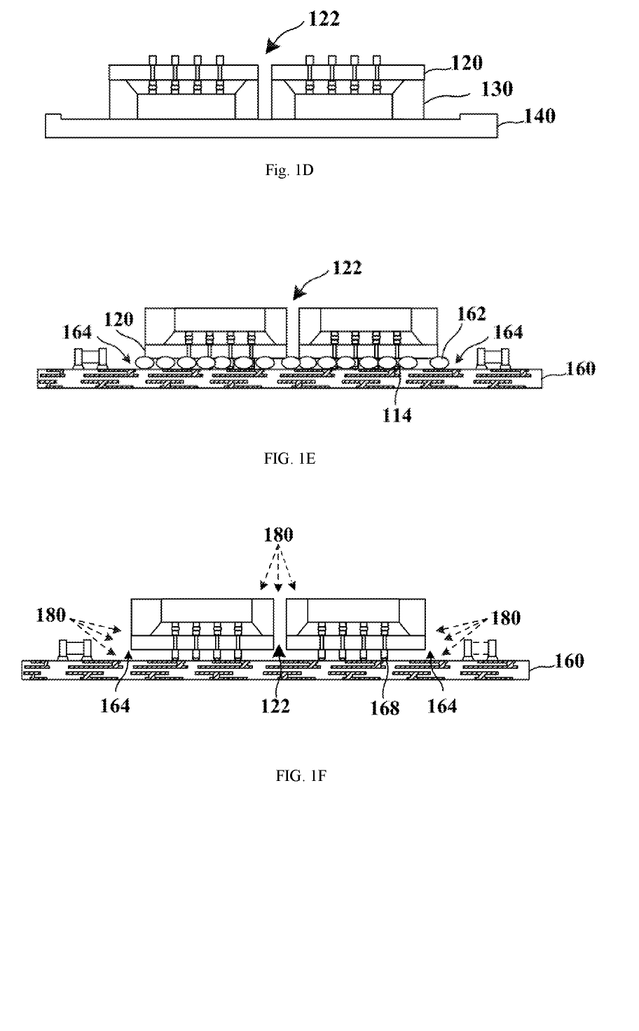

FIG. 2 illustrates a semiconductor package 200 according to an embodiment of the present application. As shown in FIG. 2, the semiconductor package 200 has an unmolded interposer module mounted on a substrate 260. The unmolded interposer has an interposer 220, which does not have any mold cap to encapsulate one or more semiconductor chips 210 mounted on the interposer 220. The semiconductor chips 210 can be mounted on the interposer 220 via a set of solder bumps 212 and preferably further via an underfill material 211. Furthermore, at least one central opening 222 may be formed in the unmolded interposer module, or particularly through the interposer 220. The other structures of the semiconductor package 200 is similar as the semiconductor package shown in FIG. 1F, and will not be elaborated herein. It can be appreciated that the central opening(s) can allow deflux chemicals to pass therethrough into a gap between the substrate and the interposer, thus removing flux material completely in the interior space of the semiconductor package during its manufacturing process, which is similar as the manufacturing process shown in FIGS. 1A to 1F.

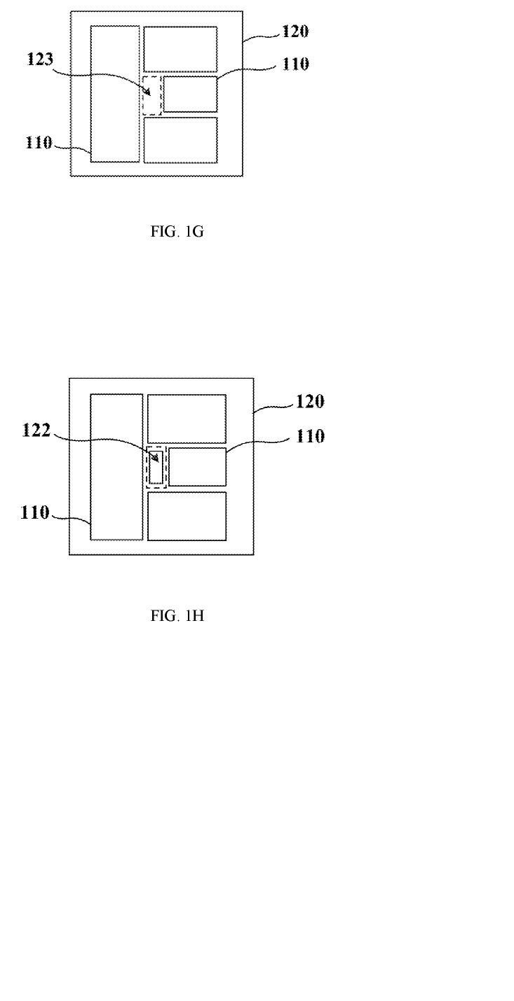

FIG. 3 illustrates a semiconductor package 300 according to an embodiment of the present application. As shown in FIG. 3, the semiconductor package 300 incorporates a plurality of semiconductor chips 310 stacked on an interposer 320 via a set of interconnect structures 312. A mold cap 330 may be formed on the interposer 320 to encapsulate the plurality of semiconductor chips 310 and the set of interconnect structures 312, and protect them from the external environment and damages. An underfill material 307 may be filled between the interposer 320 and the substrate 360 and around a solder bumps 368 to enhance the attachment of the interposer 320 to the substrate 360. In some embodiments, the mold cap 330 and the underfill material 307 may be made, partially or in all, of a polymer composite material such as epoxy resin with filler, epoxy acrylate with filler, or polymer with proper filler.

Still referring to FIG. 3, a central opening 322 is formed passing through the interposer 320 and defines a chip mounting region surrounding the central opening 322. Therefore, a deflux chemical mist can be sprayed through the central opening 322 and side slits of the interposer 322 to remove the residual flux accommodated during the later manufacturing process. In some embodiments, another molding material 331 may be dispensed to fill the central opening 322, eliminating the risk of mechanical and reliability defects in the central opening 322. In some other examples, other filler materials such as a thermally conductive material may be filled in the central opening 322. For example, the thermally conductive material can provide a heat dissipation path from the interior space of the package to the external environment.

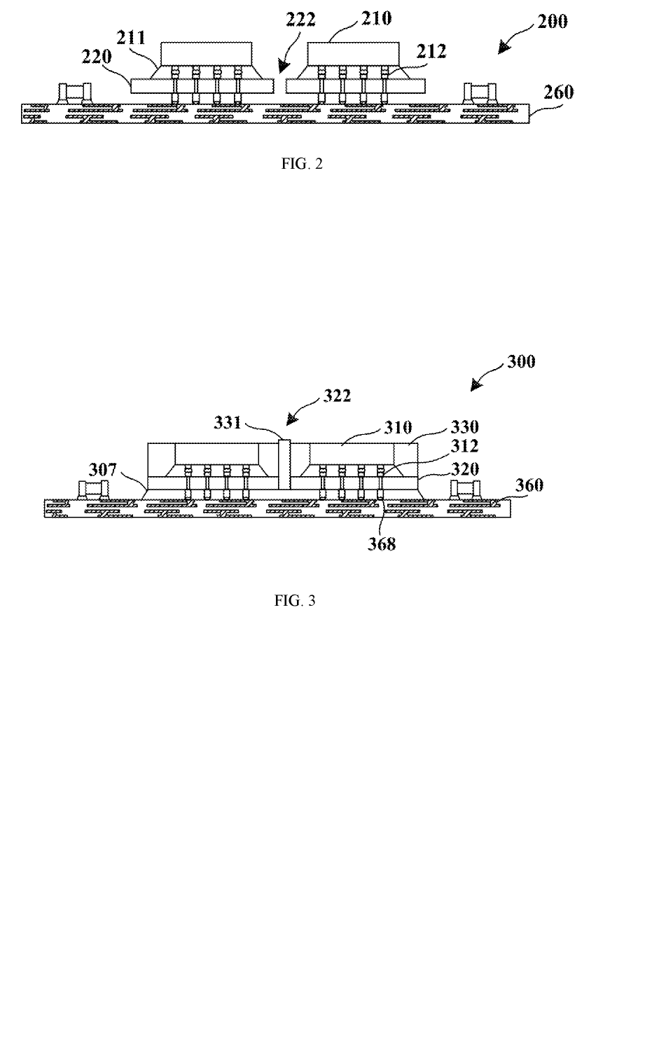

FIG. 4 illustrates a semiconductor package 400 according to an embodiment of the present application. As shown in FIG. 4, the structure of the semiconductor package 400 is similar to that of the semiconductor assembly 300 shown in FIG. 3, differing in that an encapsulant 430 is further formed in the central opening 423 and around a plurality of solder bumps 468 to encapsulate the molded interposer module including semiconductor chips 410.

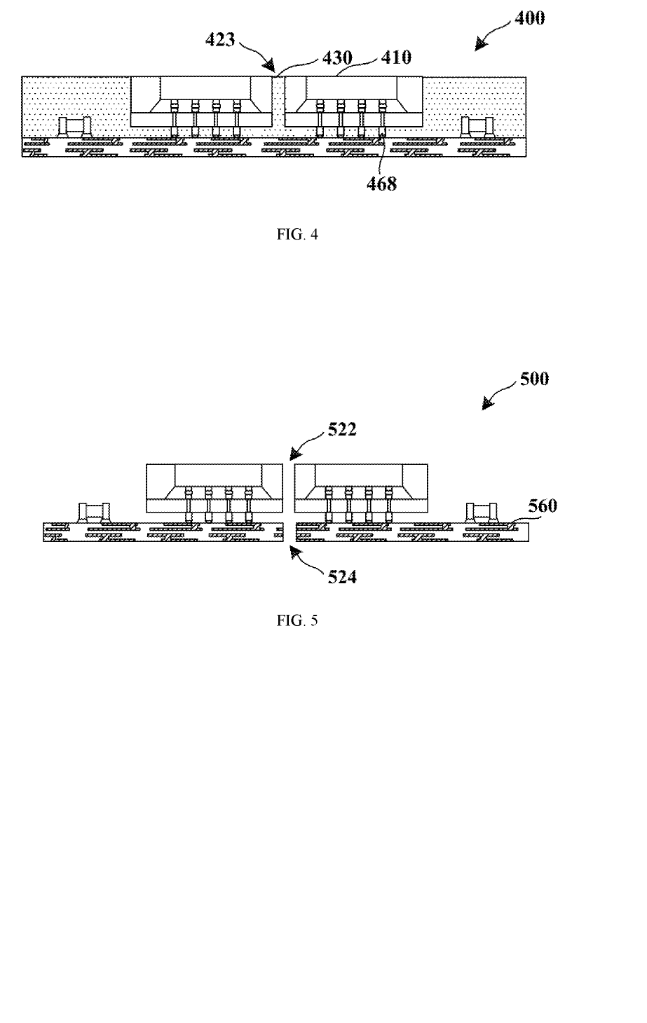

FIG. 5 illustrates a semiconductor package 500 according to an embodiment of the present application. As shown in FIG. 5, a substrate 560 has a slot 524 aligned with a central opening 522 of a molded interposer module. Therefore, a flux material dispensed between an interposer 520 and a substrate 560 can be also removed by a deflux material mist flowing through the slot 524 if a corresponding nozzle is disposed right below the slot 524 of the substrate 560, beside the mist flowing into the internal space of the semiconductor package 500 through the central opening 522 and side slits. Similar as the central opening(s) 522 of the molded interposer module, it is preferred that no conductive wires or via are formed in the region of the substrate 560 where the slot 524 is formed. Furthermore, in some preferred embodiments, the slot 524 and the central opening 522 may be filled with an encapsulant or other similar materials after the removal of the flux material. In some other examples, the slots 524 of the substrate 560 may not be aligned with the central openings 522 of the molded interposer module, which helps the lateral flow of the deflux material mist along the substrate and the interposer.

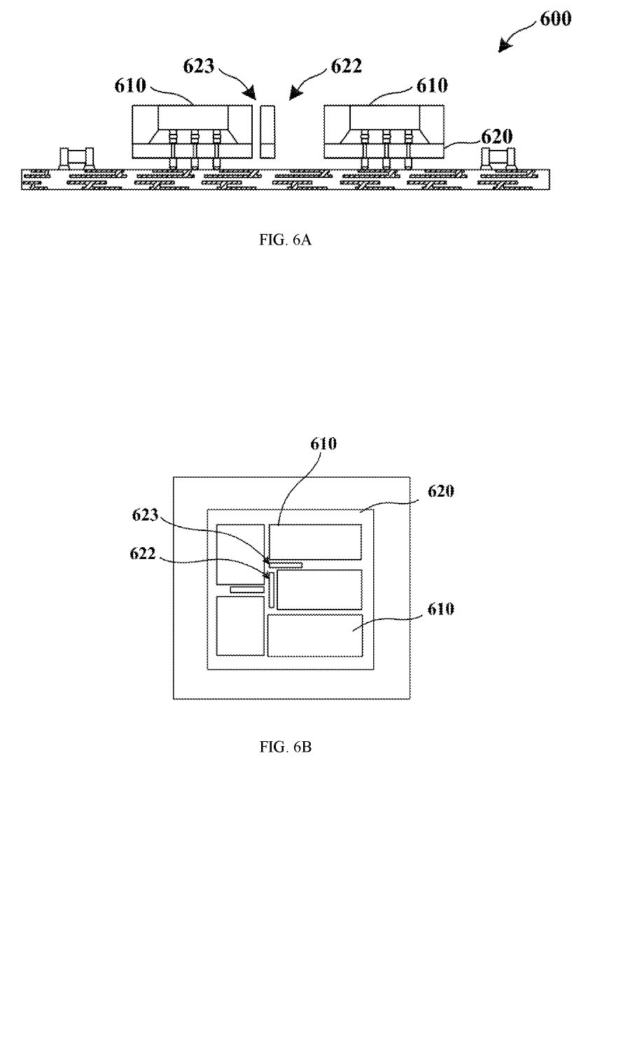

FIG. 6A illustrates a semiconductor package 600 according to an embodiment of the present application. As shown in FIG. 6A, multiple central openings 622 and 623 are formed in gaps of a plurality of semiconductor chips 610.

FIG. 6B illustrates an exemplary layout of the plurality of semiconductor chips 610 on an interposer 620 shown in FIG. 6A. As shown in FIG. 6B, three central openings 622 and 623 are formed in the gaps between adjacent ones of the plurality of semiconductor chips 610, and pass through both a mold cap and an interposer of the semiconductor package 600. These gaps may be reserved for the central openings when the semiconductor chips 610 are mounted. It should be noted that although several semiconductor chips are illustrated in FIG. 6A as an example, more semiconductor chips may be integrated within the semiconductor package 600, and more central openings may be formed between the semiconductor chips, as desired. In some embodiments, one or more slots may be similarly formed in a substrate of the semiconductor package 600, which may or may not be aligned with the central openings of molded interposer modules, as long as a deflux chemical mist can effectively flow into an internal space of the semiconductor package 600 for defluxing. In some embodiments, both the slots and the central openings may be filled with an encapsulant or similar materials.

The discussion herein includes numerous illustrative figures that show various portions of a semiconductor package and a method for forming such semiconductor package. For illustrative clarity, such figures do not show all aspects of each example semiconductor package. Any of the example packages provided herein may share any or all characteristics with any or all other packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a semiconductor package, comprising:
providing a molded interposer module, wherein the molded interposer module comprises an interposer having at least one central opening passing therethrough and a chip mounting region surrounding the at least one central opening, a plurality of semiconductor chips mounted on the chip mounting region of the interposer, and a mold cap formed on the chip mounting region of the interposer to encapsulate the plurality of semiconductor chips;
disposing the molded interposer module on a substrate via solder paste, wherein a flux material is formed around the solder paste, and the molded interposer module and the substrate define together a space to accommodate the solder paste, and the space has side slits that fluidly communicate the space with an external environment;
reflowing the solder paste to form a plurality of solder bumps; and
spraying a deflux chemical mist towards the plurality of solder bumps through the at least one central opening of the interposer and the side slits.

2. The method of claim 1, wherein providing a molded interposer module comprises:
mounting the plurality of semiconductor chips on the chip mounting region of the interposer;
forming the mold cap on the interposer to encapsulate the plurality of semiconductor chips;
attaching the mold cap onto a carrier;
etching through the interposer and the mold cap to form the at least one central opening, thereby forming the molded interposer module; and
removing the molded interposer module from the carrier.

3. The method of claim 1, disposing the molded interposer module on a substrate comprises:
forming on at least one of the substrate and the molded interposer module the solder paste;
forming around the solder paste the flux material; and
attaching the molded interposer module onto the substrate via the plurality of solder bumps.

4. The method of claim 1, wherein after the step of disposing the molded interposer module on a substrate, the method further comprises:
attaching additional electronic devices directly on the substrate around the molded interposer module.

5. The method of claim 4, wherein after the step of spraying a deflux chemical mist towards the plurality of solder bumps, the method further comprises:
forming the mold on the substrate to encapsulate the molded interposer module and the additional electronic devices.

6. The method of claim 1, wherein after the step of spraying a deflux chemical mist towards the plurality of solder bumps, the method further comprises:
filling the at least one central opening of the interposer by dispensing.

7. A semiconductor package, comprising:
a substrate;
an interposer mounted on the substrate, and having at least one central opening passing therethrough and a chip mounting region surrounding the at least one central opening; and
a plurality of semiconductor chips mounted on the chip mounting region of the interposer.

8. The semiconductor package of claim 7, further comprising:
a mold cap formed on the chip mounting region of the interposer to encapsulate the plurality of semiconductor chips.

9. The semiconductor package of claim 8, wherein the mold cap is further formed in the at least one central opening and between the plurality of semiconductor chips.

10. The semiconductor package of claim 7, wherein the substrate has at least one slot passing therethrough and connected with the at least one central opening.

11. The semiconductor package of claim 7, wherein the plurality of semiconductor chips include at least three semiconductor chips, and each of the at least one central opening is aligned with a gap between two of the plurality of semiconductor chips.

12. The semiconductor package of claim 7, further comprising a plurality of solder bumps disposed between the interposer and the substrate and for providing electrical connection therebetween.

13. The semiconductor package of claim 12, further comprising an underfill material formed between the interposer, the substrate, and each of the plurality of solder bumps.

14. A method for forming a semiconductor package, comprising:
providing an unmolded interposer module, wherein the unmolded interposer module comprises an interposer having at least one central opening passing therethrough and a chip mounting region surrounding the at least one central opening, and a plurality of semiconductor chips mounted on the chip mounting region of the interposer;
disposing the unmolded interposer module on a substrate via solder paste, wherein a flux material is formed around the solder paste, and the unmolded interposer module and the substrate define together a space to accommodate the solder paste, and the space has side slits that fluidly communicate the space with an external environment;
reflowing the solder paste to form a plurality of solder bumps; and
spraying a deflux chemical mist towards the plurality of solder bumps through the at least one central opening of the interposer and the side slits.
